(19) United States
(12) Patent Application Publication
(10) Pub. No.: US 2004/0251965 A1
(43) Pub. Date: Dec. 16, 2004

(54) Differential amplifier with temperature compensating function

(76) Inventors: Tetsuya Ueda, Tokyo (JP); Yoshinori Takahashi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/493,312

(22) PCT Filed: Oct. 4, 2002
(86) PCT No.: PCT/JP02/10380

(51) Int. Cl. H03F 3/45

(52) U.S. Cl. 330/256

(57) ABSTRACT

A temperature compensated differential amplifier includes a first differential amplifier and a second differential amplifier. The first differential amplifier includes a feedback resistance, and has a gain proportional to temperature. The second differential amplifier is connected to the output side of the first differential amplifier, includes no feedback resistance, and has a gain inversely proportional to the temperature. The first differential amplifier carries out the temperature compensation of the gain and distortion of the second differential amplifier.

### TECHNICAL FIELD

The present invention relates to a temperature compensated differential amplifier for carrying out temperature compensation of the gain and distortion of a feedback resistance-less differential amplifier.

### BACKGROUND ART

FIG. 1 is a circuit diagram showing a conventional feedback resistance-less differential amplifier. In FIG. 1, the reference symbol Vcc designates a power supply, GND designates a ground, and RL designates a load resistance. Reference symbols Q1 and Q2 each designate a transistor, and the reference symbol C1 designates a constant current source.

Next, the operation will be described.

A differential input current ΔI is expressed by the following expression (1).

ΔI=I0·tan h(ΔV/2V_{T}) (1)

where I0 is the current of the constant current source C1, ΔV designates a differential input voltage, and V_{T}=kT/q, where k is Boltzmann's constant, T is an absolute temperature, and q is the magnitude of the charge on the carrier.

When the foregoing expression (1) is expanded in a series, the first term represents a gain, and the second and subsequent terms all represent distortion components. Among the distortion components, the third term is the most dominant component. Thus, when expanding the foregoing expression (1) in a series, the first term Gain, and the distortion HD3 defined as the ratio of the third term to the first term, are given by the following expressions (2) and (3).

Gain=a1(ΔV/T) (2)

HD3=(a3/a1)·(ΔV/T)² (3)

where a1 is the coefficient of the first term, and a3 is the coefficient of the third term.

With the foregoing configuration, the conventional feedback resistance-less differential amplifier has a characteristic that its gain and distortion are inversely proportional to the absolute temperature T as represented by the foregoing expressions (2) and (3). Accordingly, as the temperature increases, the gain is reduced, and the distortion is lowered (improved).

Thus, the conventional feedback resistance-less differential amplifier has a problem in that the gain and distortion vary depending the absolute temperature T.

The present invention is implemented to solve the foregoing problem. Therefore it is an object of the present invention to provide a temperature compensated differential amplifier capable of making temperature compensation of the gain and distortion of the feedback resistance-less differential amplifier.

### DISCLOSURE OF THE INVENTION

A temperature compensated differential amplifier as described in claim 1 includes: a first differential amplifier including a feedback resistance, and having a gain proportional to temperature; and a second differential amplifier connected to an output side of the first differential amplifier, including no feedback resistance, and having a gain inversely proportional to the temperature.

Thus, it can cancel out the temperature characteristics of the gains of the first differential amplifier and second differential amplifier, thereby being able to make the temperature compensation of the gain of the second differential amplifier without a feedback resistance. In addition, although the distortion of the second differential amplifier has the characteristic inversely proportional to the temperature, since the second differential amplifier is supplied with the signal with the gain characteristic proportional to the temperature from the first differential amplifier, it can offer an advantage of enabling the second differential amplifier without the feedback resistance to make the temperature compensation of the distortion.

The temperature compensated differential amplifier as described in claim 2 has the gain of the first differential amplifier controlled by an external voltage.

Thus, it offers an advantage of being able to control the gain by the external voltage of the first differential amplifier, and to implement the temperature compensated differential amplifier with a wide variable range.

The temperature compensated differential amplifier as described in claim 3 provides the first differential amplifier with a constant current circuit for generating a temperature-proportional current; and an amplifier for amplifying a differential input in response to a current with a ratio equal to a ratio of the temperature-proportional current generated by the constant current circuit, and for outputting an amplified signal as a differential output.

Thus, it offers an advantage of being able to implement the first differential amplifier with the gain proportional to the temperature.

The temperature compensated differential amplifier as described in claim 4 provides the first differential amplifier with a first constant current circuit for generating a temperature-independent constant current; a second constant current circuit for generating a temperature-proportional current; an input circuit for converting a differential input to a signal corresponding to the temperature-independent constant current generated by the first constant current circuit; and an output circuit for converting the signal passing through conversion by the input circuit to a signal corresponding to the temperature-proportional current generated by the second constant current circuit, and for making differential output of the signal converted by the output circuit.

Thus, it offers an advantage of being able to implement the first differential amplifier with the gain proportional to the temperature.

The temperature compensated differential amplifier as described in claim 5 provides the first differential amplifier with a first constant current circuit for generating a temperature-independent, external-voltage-proportional constant current; a second constant current circuit for generating a temperature-proportional, external-voltage-independent constant current; a current generating circuit for generating a temperature-proportional and external-voltage-proportional current in response to the currents generated by the first and second constant current circuits; and an amplifier for amplifying a differential input in response to a current with a ratio equal to a ratio of the temperature-proportional and external-voltage-proportional current generated by the current generating circuit, and for outputting an amplified signal as a differential output.

Thus, it offers an advantage of being able to implement the first differential amplifier whose gain is controlled by the external voltage.

### BRIEF DESCRIPTION OF THE DRAWINGS

FIG. 1 is a circuit diagram showing a conventional feedback resistance-less differential amplifier;

FIG. 2 is a block diagram showing a configuration of an embodiment 1 of the temperature compensated differential amplifier in accordance with the present invention;

FIG. 3 is a circuit diagram showing a detailed configuration of a first differential amplifier of an embodiment 2 in accordance with the present invention;

FIG. 4 is a circuit diagram showing a detailed configuration of a second differential amplifier of the embodiment 2 in accordance with the present invention;

FIG. 5 is a circuit diagram showing a detailed configuration of a first differential amplifier of an embodiment 3 in accordance with the present invention;

FIG. 6 is a block diagram showing a configuration of an embodiment 4 of the temperature compensated differential amplifier in accordance with the present invention;

FIG. 7 is a circuit diagram showing a detailed configuration of a part of a first differential amplifier of an embodiment in accordance with the present invention; and

FIGS. 8A-8D are characteristic diagrams illustrating currents at various portions corresponding to temperatures and external voltages.

### BEST MODE FOR CARRYING OUT THE INVENTION

The best mode for carrying out the invention will now be described with reference to the accompanying drawings to explain the present invention in more detail.

Embodiment 1

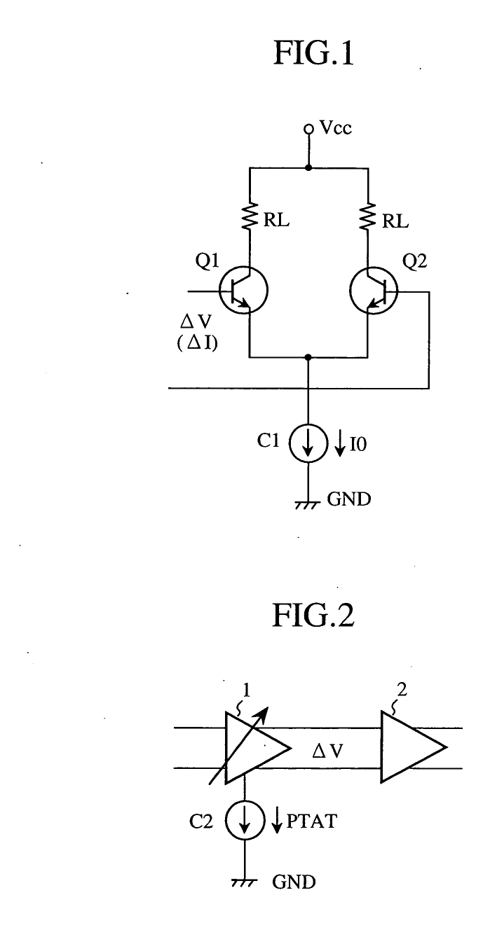

FIG. 2 is a block diagram showing a configuration of an embodiment 1 of the temperature compensated differential amplifier in accordance with the present invention. In FIG. 2, the reference numeral 1 designates a differential amplifier (first differential amplifier) that includes a feedback resistance and has a gain with a characteristic directly proportional to the absolute temperature. The reference symbol C2 designates a constant current source for causing a temperature-proportional current PTAT (Proportionality To Absolute Temperature) to flow. The reference numeral 2 designates a differential amplifier (second differential amplifier), which corresponds to the conventional differential amplifier as shown in FIG. 1, for example. It is connected to the differential amplifier 1 as the next stage, does not include a feedback resistance, and has a gain inversely proportional to the absolute temperature.

Next, the operation will be described.

As for the feedback resistance-less differential amplifier as shown in FIG. 1, its gain and distortion are inversely proportional to the absolute temperature. Thus, its gain is reduced and it distortion is lowered as the temperature increases.

In view of this, as illustrated in FIG. 2, the embodiment 1 includes, before the feedback resistance-less differential amplifier 2, the differential amplifier 1 that has the feedback resistance and the gain directly proportional to the absolute temperature.

Generally, it is a characteristic of a differential amplifier with the feedback resistance that its gain and distortion are almost independent of the absolute temperature. The present embodiment 1 combines the differential amplifier with such a characteristic with a circuit such as a constant current source that causes a current proportional to the absolute temperature to flow, thereby facilitating the implementation of the differential amplifier 1 having the gain directly proportional to absolute temperature.

The differential voltage ΔV output from the differential amplifier 1 can be expressed as ΔV=V0·T because its gain is proportional to the absolute temperature T. Substituting ΔV=V0·T into the foregoing expressions (2) and (3) yields the following expressions (4) and (5).

Gain=a1(ΔV/T)=a1(V0·T/T)=a1·V0 (4)

$$\begin{matrix}HD3 = ( a3 / a1 ) \cdot {( Δ V / T )}^{2} \\ = ( a3 / a1 ) \cdot {( V0 \cdot T / T )}^{2} \\ = ( a3 / a1 ) \cdot {( V0 )}^{2}\end{matrix} \qquad ( 5 )$$

As the foregoing expression (4) and (5) indicate, the gain and distortion are independent of the absolute temperature T, thereby being able to achieve the temperature compensation of the gain and distortion of the feedback resistance-less differential amplifier 2.

Thus, the temperature characteristics of the gains of the differential amplifiers 1 and 2 are canceled out. In addition, although the distortion of the differential amplifier 2 is inversely proportional to the absolute temperature T, the distortion throughout the differential amplifiers 1 and 2 can be made constant against the absolute temperature T by supplying the differential amplifier 2 with the input with the gain characteristic proportional to the absolute temperature T from the differential amplifier 1.

Embodiment 2

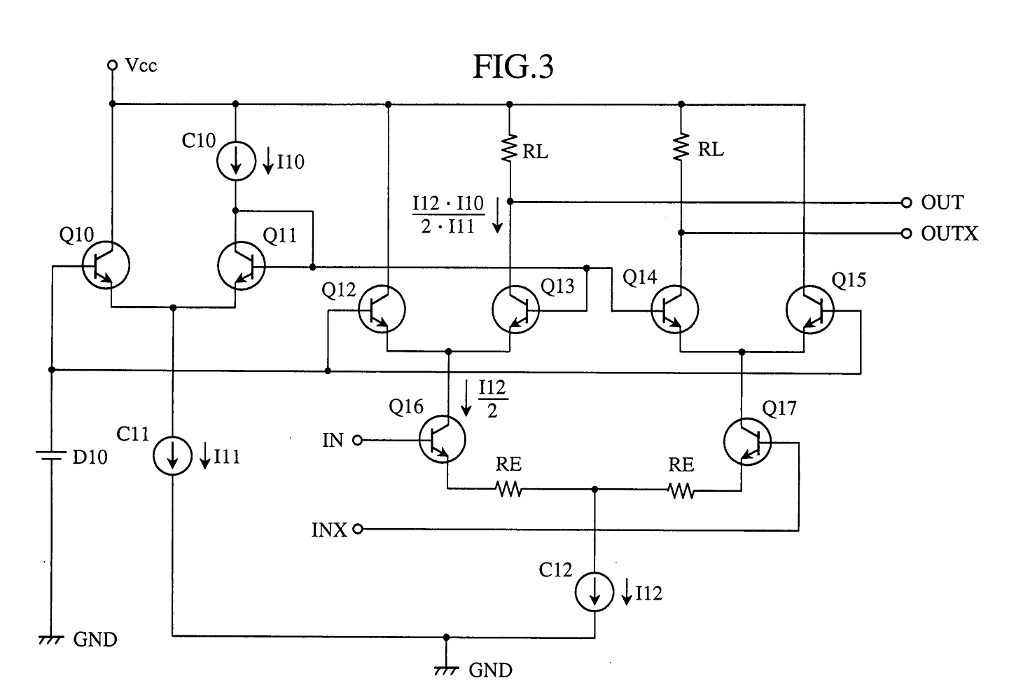

FIG. 3 is a circuit diagram showing a detailed configuration of a first differential amplifier of an embodiment 2 in accordance with the present invention. It shows the detail of the differential amplifier 1 of FIG. 2. In FIG. 3, the reference symbol Vcc designates a power supply, and GND designates a ground.

The reference symbol C10 designates a constant current source for causing a temperature-proportional current I10 to flow. Reference symbols Q10 and Q11 each designate a transistor, and the reference symbol C11 designates a constant current source for causing a temperature-independent constant current I11 to flow. All these components constitute a constant current circuit.

The reference symbol RL designates a load resistance, and OUT and OUTX designate a differential output terminal. Reference symbols Q12-Q15 each designates a transistor, IN and INX designate a differential input terminal, and Q16 and Q17 each designate a transistor. The reference symbol RE designates a feedback resistance, and C12 designates a constant current source for causing a temperature-independent constant current I12 to flow. All these components constitute an amplifier.

The reference symbol D10 designates a power supply for operating a current mirror circuit including the transistors Q10-Q15.

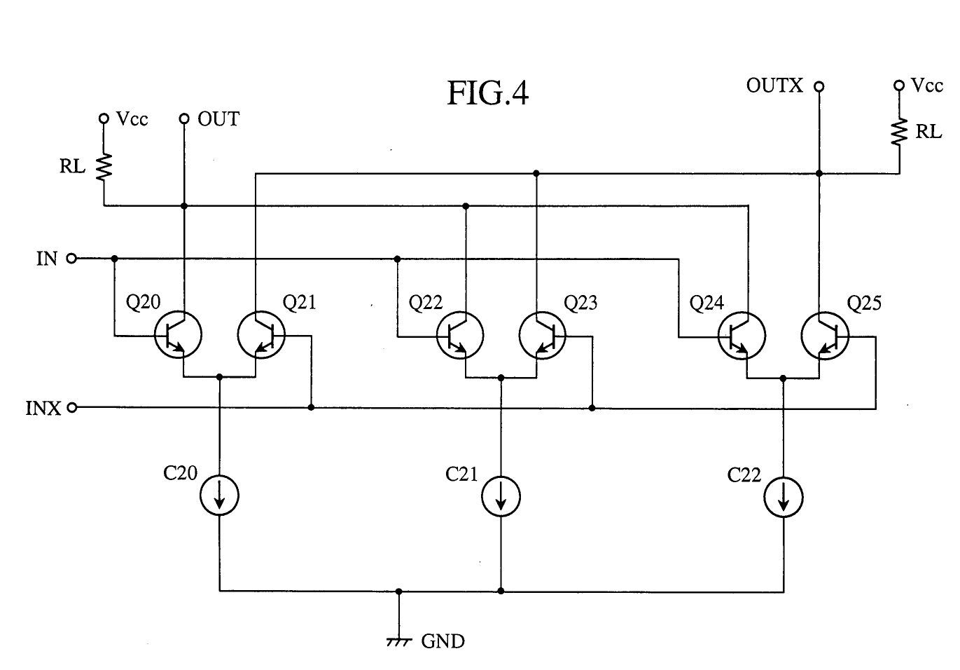

FIG. 4 is a circuit diagram showing a detailed configuration of a second differential amplifier of the embodiment 2 in accordance with the present invention. It shows the detail of the differential amplifier 2 of FIG. 2. In FIG. 4, reference symbols Q20-Q25 each designate a transistor, and C20-C22 each designate a constant current source for causing a temperature-independent constant current to flow.

Next, the operation will be described.

In the differential amplifier 1 as shown in FIG. 3, the transistor Q11 passes the temperature-proportional current I10 from the constant current source C10, and the transistor Q10 passes the differential current between the temperature-independent constant current I11 and temperature-proportional current I10.

Each pair of the transistors Q10 and Q11, the transistors Q12 and Q13, and the transistors Q14 and Q15 constitutes a current mirror circuit so that the currents flow through them at the same ratio. Since the constant current source C12 causes the temperature-independent constant current I12 to flow, the transistor Q16 passes the current I12/2, and the transistor Q13 passes the temperature-proportional current corresponding to I12·I10/2·I11.

The differential input from the differential input terminal IN and INX is amplified, and is output from the differential output terminal OUT and OUTX. The gain of the differential amplifier 1 of FIG. 3 is given by the following expression (6).

Gain=(RL/RE)·(I12·I10/2·I11) (6)

where RL is the load resistance and RE is the feedback resistance.

Since the gain is expressed by a function including the temperature-proportional current I10 as a numerator, the differential amplifier 1 with the gain directly proportional to the absolute temperature is implemented.

On the other hand, the differential amplifier 2 as shown in FIG. 4 receives the differential output of the differential amplifier 1 at the differential input terminal IN and INX. The differential amplifier 2 amplifies the input with three differential pairs of transistors Q20 and Q21, transistors Q22 and Q23, and transistors Q24 and Q25, and outputs the amplified signal from the differential output terminal OUT and OUTX. Although FIG. 4 shows three differential pairs, two or one differential pair can meet the function.

As described in the foregoing embodiment 1, the amplifier 2 is characterized by the gain inversely proportional to the absolute temperature. Accordingly, combining the differential amplifier 2 with the differential amplifier 1 can cancel out the temperature characteristics of their gains and distortion, thereby being able to achieve the temperature compensation.

Embodiment 3

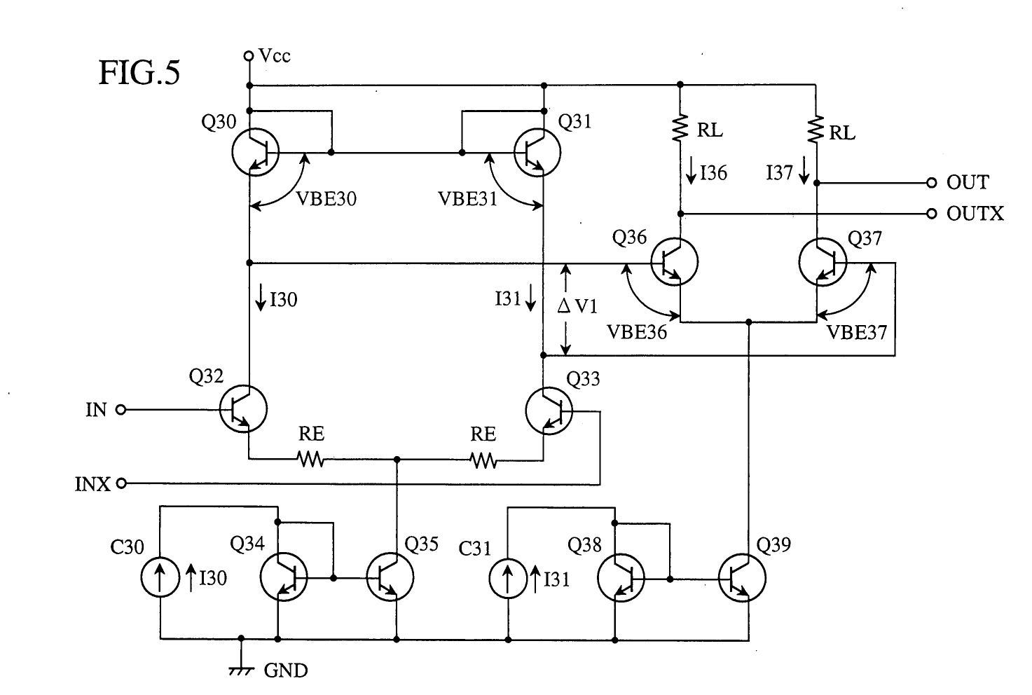

FIG. 5 is a circuit diagram showing a detailed configuration of a first differential amplifier of an embodiment 3 in accordance with the present invention. It shows another example of the details of the differential amplifier 1 of FIG. 2. In FIG. 5, reference symbols Q30-Q33 each designate a transistor, IN and INX designate a differential input terminal, and the reference symbol RE designates a feedback resistance. All these components constitute an input circuit.

The reference symbol C30 designates a constant current source for causing a temperature-independent constant current I30 to flow, and reference symbols Q34 and Q35 each designate a transistor. All these components constitute a first constant current circuit.

The reference symbol RL designate a load resistance, and OUT and OUTX designate a differential output terminal. Reference symbols Q36 and Q37 each designate a transistor. All these components constitute an output circuit.

The reference symbol C31 designates a constant current source for causing a temperature-proportional current I31 to flow, and reference symbols Q38 and Q39 each designate a transistors. All these components constitute a second constant current circuit.

Next, the operation will be described.

In FIG. 5, the relationships between the voltage ΔV1 and base-emitter voltages VBE30, VBE31, VBE36 and VBE37 of the transistors Q30, Q31, Q36 and Q37 can be given by the following expression (7).

ΔV1=VBE36−VBE37=VBE30−VBE31 (7)

$$∴ {V}_{T} \cdot ln ( I36 / Is ) - {V}_{T} \cdot ln ( I37 / Is ) = {V}_{T} \cdot ln ( I30 / Is ) - {V}_{T} \cdot ln ( I31 / Is ) \\ ∴ I36 / 137 = I30 / I31 \qquad ( 8 )$$

where Is is a saturation current.

As seen from the foregoing expression (8), the ratio of the currents flowing through the differential pair transistors Q30 and Q31 is equal to the ratio of currents flowing through the differential pair transistors Q36 and Q37.

Since the constant current source C30 causes the temperature-independent constant current I30 to flow, a temperature-independent constant current also flows through the transistor Q35. As for the differential input to the differential input terminal IN and INX, although it is converted to the currents I30 and I31 through the transistor Q32 and feedback resistance RE and the transistor Q33 and feedback resistance RE, these currents are independent of the temperature.

The currents I30 and I3 flowing through the differential pair of the transistors Q30 and Q31 cause the same ratio of currents I36 and I37 to flow through the differential pair of the transistors Q36 and Q37. Since the constant current source C31 causes the temperature-proportional current I31 to flow, the temperature-proportional current also flows through the transistor Q39 so that the currents I36 and I37 become the temperature-proportional current.

The differential input to the differential input terminal IN and INX is amplified and output from the differential output terminal OUT and OUTX. In this case, the gain of the differential amplifier 1 of FIG. 5 is given by the following expression (9).

Gain=(RL/RE)·(I31/I30) (9)

where RL is the load resistance and RE is the feedback resistance.

In this way, the gain is expressed by a function including the temperature-proportional current I31 as a numerator. Therefore the differential amplifier 1 with the gain directly proportional to absolute temperature can be implemented.

Embodiment 4

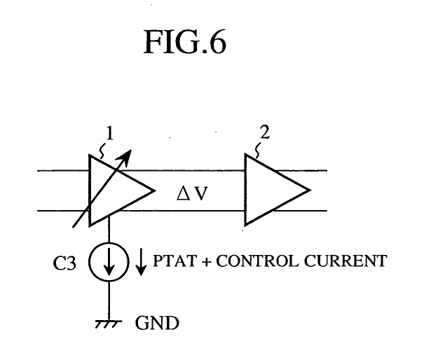

FIG. 6 is a block diagram showing a configuration of an embodiment 4 of the temperature compensated differential amplifier in accordance with the present invention. In FIG. 6, the reference symbol C3 designates a constant current source that causes the temperature-proportional current PTAT and a control current corresponding to an external voltage to flow. The remaining configuration is the same as that of FIG. 2.

Next, the operation will be described.

As shown in FIG. 6, the present embodiment 4 is configured such that the temperature-proportional current PTAT and the control current corresponding the external voltage are combined to flow through the differential amplifier 1.

Thus, the present embodiment can control the gain of the differential amplifier 1 by the external voltage, thereby being able to implement the temperature compensated differential amplifier with a wide variable range in connection with the feedback resistance-less differential amplifier 2.

Embodiment 5

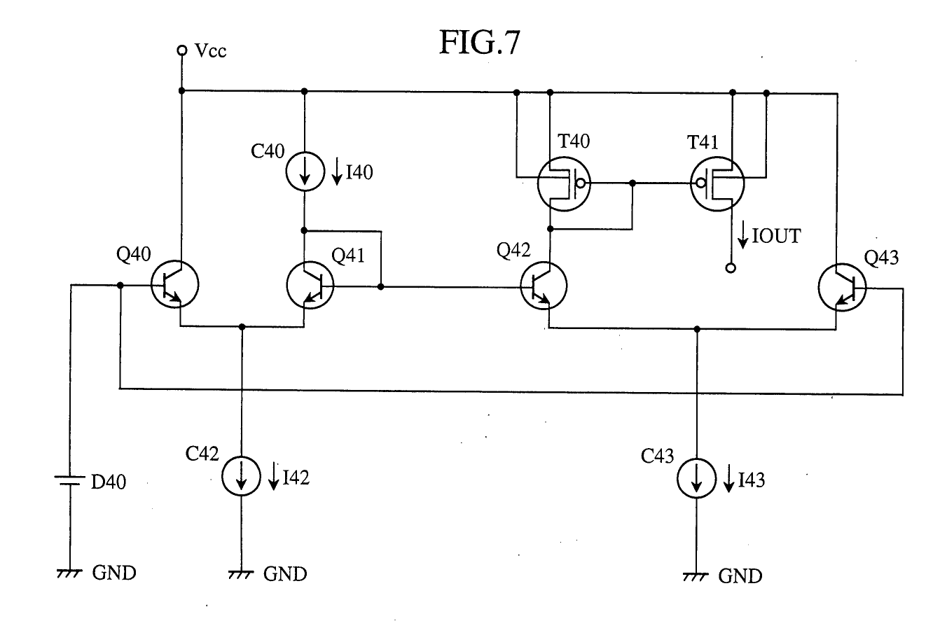

FIG. 7 is a circuit diagram showing a detailed configuration of a part of the first differential amplifier of an embodiment 5 in accordance with the present invention, which shows part of the constant current source C3 of FIG. 6 in detail. More specifically, the circuit as shown in FIG. 7 is installed instead of the constant current source C10 in FIG. 3. The power supply Vcc and current output terminal IOUT in FIG. 7 are connected to the power supply Vcc and the collector of the transistor Q11 in FIG. 3.

In FIG. 7, the reference symbol C40 designates a constant current source for causing a temperature-independent constant current I40 proportional to an external voltage to flow. The constant current source C40 constitutes a first constant current circuit.

Reference symbols Q40 and Q41 each designate a transistor, and the reference symbol C42 designates a constant current source for causing a temperature-independent and external-voltage-independent constant current I42 to flow.

Reference symbols T40 and T41 each designate a FET, and Q42 and Q43 each designate a transistor. All these components constitute a current generating circuit.

The reference symbol C43 designates a constant current source that causes a temperature-proportional and external-voltage-independent constant current I43 to flow. It constitutes a second constant current circuit.

The reference numeral D40 designates a power supply for operating the current mirror circuit composed of transistors Q40-Q43.

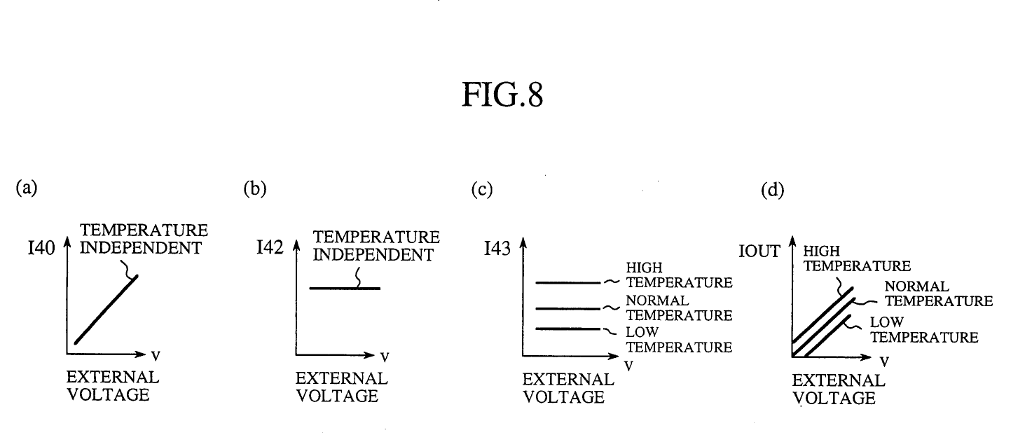

FIGS. 8(a)-8(d) are characteristic diagrams illustrating currents at various parts corresponding to the temperature and external voltage: FIG. (a) illustrates the characteristics of the constant current source C40; FIG. 8(b) those of the constant current source C42; FIG. 8(c) those of the constant current source C43, and FIG. 8(d) those of the current output terminal IOUT.

Next, the operation will be described.

In FIG. 7, the constant current source C40 causes the temperature-independent, external-voltage-proportional current I40 as illustrated in FIG. 8(a) to flow through the transistor Q41. On the other hand, the constant current source C42 causes the temperature- and external-voltage-independent current I42 as illustrated in FIG. 8(b) to flow. Thus, the differential current between the current I42 and current I40 flows through the transistor Q40.

The transistors Q40 and Q43, the transistors Q41 and Q42 and FETs T40 and T41 each constitute a current mirror circuit so that they each cause the same ratio of currents to flow through them. In addition, the constant current source C43 causes the temperature-proportional, external-voltage-independent current I43 as illustrated in FIG. 8(c) to flow. Accordingly, the current IOUT as illustrated in FIG. 8(d) and given by the following expression (10) flows from the FET T41 to the current output terminal IOUT.

IOUT=I40·I43/I42 (10)

The current IOUT is a temperature- and external-voltage-proportional current.

The current IOUT is supplied to the collector of the transistor Q11 instead of the constant current source C10 in FIG. 3.

As given by the foregoing expression (6), the gain of the differential amplifier 1 of FIG. 3 is proportional to the temperature-proportional current I10. Using the temperature- and external-voltage-proportional current IOUT instead of the temperature-proportional current I10 makes it possible to control the gain of the differential amplifier 1 of FIG. 6 in proportion to both the absolute temperature and external voltage.

In this way, the present embodiment can implement the differential amplifier 1 with the gain controlled by the external voltage.

### INDUSTRIAL APPLICABILITY

As described above, the temperature compensated differential amplifier in accordance with the present invention is suitable for making the temperature compensation of the gain and distortion of the differential amplifier 2 by operating the differential amplifier 2 in conjunction with the differential amplifier 1.

What is claimed is:

1. A temperature compensated differential amplifier comprising:
a first differential amplifier including a feedback resistance, and having a gain proportional to temperature; and
a second differential amplifier connected to an output side of said first differential amplifier, including no feedback resistance, and having a gain inversely proportional to the temperature.

2. The temperature compensated differential amplifier according to claim 1, wherein said first differential amplifier has its gain controlled by an external voltage.

3. The temperature compensated differential amplifier according to claim 1, wherein said first differential amplifier comprises:
a constant current circuit for generating a temperature-proportional current; and
an amplifier for amplifying a differential input in response to a current with a ratio equal to a ratio of the temperature-proportional current generated by said constant current circuit, and for outputting an amplified signal as a differential output.

4. The temperature compensated differential amplifier according to claim 1, wherein said first differential amplifier comprises:
a first constant current circuit for generating a temperature-independent constant current;
a second constant current circuit for generating a temperature-proportional current;
an input circuit for converting a differential input to a signal corresponding to the temperature-independent constant current generated by said first constant current circuit; and
an output circuit for converting the signal passing through conversion by said input circuit to a signal corresponding to the temperature-proportional current generated by said second constant current circuit, and for making differential output of the signal converted by said output circuit.

5. The temperature compensated differential amplifier according to claim 2, wherein said first differential amplifier comprises:
a first constant current circuit for generating a temperature-independent, external-voltage-proportional constant current;
a second constant current circuit for generating a temperature-proportional, external-voltage-independent constant current;
a current generating circuit for generating a temperature-proportional and external-voltage-proportional current in response to the currents generated by said first and second constant current circuits; and
an amplifier for amplifying a differential input in response to a current with a ratio equal to a ratio of the temperature-proportional and external-voltage-proportional current generated by said current generating circuit, and for outputting an amplified signal as a differential output.
